(19) United States
(12) Patent Application Publication
(10) Pub. No.: US 2008/0003752 A1
(43) Pub. Date: Jan. 3, 2008

(54) Gate dielectric materials for group III-V enhancement mode transistors

(76) Inventors: Matthew V. Metz, Hillsboro, OR (US); Mark L. Doczy, Beaverton, OR (US); Suman Datta, Beaverton, OR (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/479,903

(22) Filed: Jun. 30, 2006

(51) Int. Cl. H01L 21/336; H01L 21/265

(52) U.S. Cl. 438/285; 438/518; 257/E29.296; 257/E21.619

(57) ABSTRACT

A method for fabricating a transistor having a Group III-V semiconductor substrate with an oxygen-free dielectric disposed between the substrate and a gate is described.

### FIELD OF THE INVENTION

The invention relates to the field of semiconductor devices fabricated from materials found in Group III and Group V of the Periodic Table, hereinafter Group III-V materials, elements or compounds.

### PRIOR ART AND RELATED ART

Most integrated circuits today are based on silicon, a Group IV element of the Periodic Table. Compounds of Group III-V elements such as gallium arsenide (GaAs), indium antimonide (InSb), and indium phosphide (InP) are known to have far superior semiconductor properties than silicon, including higher electron mobility and saturation velocity. Unlike the Group III-V compounds, silicon easily oxidizes to form an almost perfect electrical interface. This gift of nature makes possible the near total confinement of charge with a few atomic layers of silicon dioxide. In contrast, oxides of Group III-V compounds are of poor quality, for instance they contain defects, trap charges, and are chemically complex.

Quantum well field-effect transistors (QWFET) have been proposed based on a Schottky metal gate and an InSb well. They show promise in lowering active power dissipation compared to silicon-based technology, as well as improved high frequency performance. Unfortunately, the off-state gate leakage current is high because of the low Schottky barrier from Fermi level pinning of the gate metal on, for example, an InSb/AlInSb surface.

The use of a high-k gate insulator has been proposed for QWFETs. See, as an example, Ser. No. 11/208,378, filed Jan. 3, 2005, entitled “Quantum Well Transistor Using High Dielectric Constant Dielectric Layer.” However, there are problems in interfacing between a high-k material and, for instance, the InSb/AlInSb surface.

Another approach for providing an oxide in a Group III-V device is to use a thin chalcogenide interface region between an oxygen-containing dielectric and a Group III-V containment layer. See “Dielectric Interface for Group III-V Semiconductor Device,” Ser. No. 11/292,399, filed Nov. 30, 2005.

### BRIEF DESCRIPTION OF THE DRAWINGS

FIG. 1 is a cross-sectional, elevation view showing a Group III-V semiconductor material and a gate electrode with an oxygen-containing dielectric.

FIG. 2 is a cross-sectional, elevation view of a Group III-V substrate with an oxygen-free dielectric layer.

FIG. 3 is a cross-sectional, elevation view of a Group III-V substrate showing an oxygen-free dielectric buffer layer.

FIG. 4 is an X-ray photo-electron spectroscopy (XPS) graph used to show the lack of antimony-oxygen bands at the interface between the indium antimonide compound and the oxygen-free dielectric layer.

FIG. 5 is an XPS graph used to show the lack of indium-oxygen bands at the interface between the indium antimonide compound and the oxygen-free dielectric layer.

### DETAILED DESCRIPTION

A process is described for providing a non-oxygen containing dielectric layer on a Group III-V substrate. In the following description, numerous specific chemistries are described, as well as other details, in order to provide a thorough understanding of the present invention. It will be apparent to one skilled in the art, that the present invention may be practiced without these specific details. In other instances, well-known processing steps are not described in detail in order to not unnecessarily obscure the present invention.

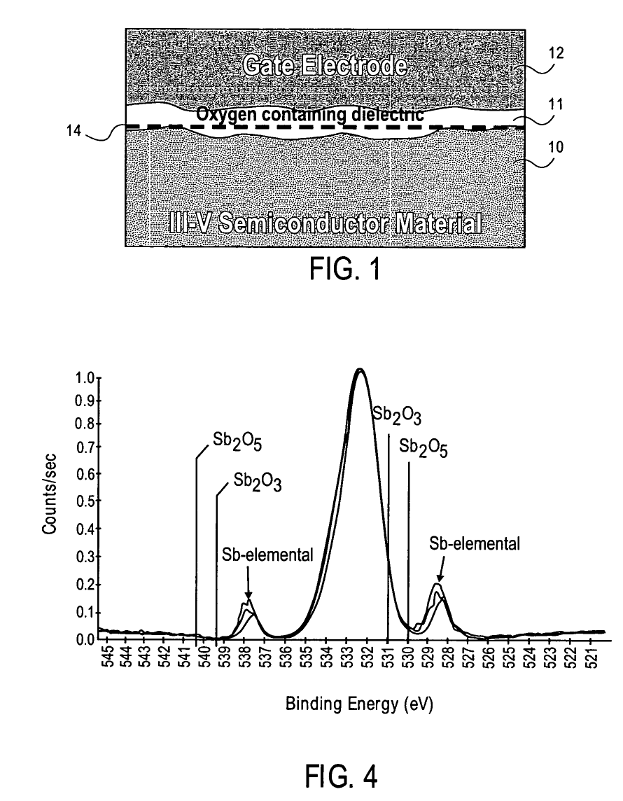

In FIG. 1, a Group III-V monocrystalline semiconductor substrate 10 is illustrated such as an indium antimonide (InSb) substrate. Ideally, a dielectric is formed between the Group III-V material and a gate electrode 12, shown in FIG. 1 to provide an enhancement mode transistor with a source and drain region. Very often the dielectric is an oxygen-containing dielectric since such dielectrics are easily formed or because a native oxide exists on a surface exposed to the atmosphere. However, in the case of a Group III-V material, reliable, uniform oxides are seemingly impossible to form. Rather, as shown by the oxide 11 in FIG. 1, they are non-uniformly formed and, once formed, contain defects and trapped charge. The dotted line 14 in FIG. 1 represents the original surface of the substrate 10. As can be seen, the oxide layer 11 is not uniformly formed relative to line 14. Consequently, it is difficult to fabricate a high performance semiconductor device on a Group III-V substrate and use an oxide-based dielectric.

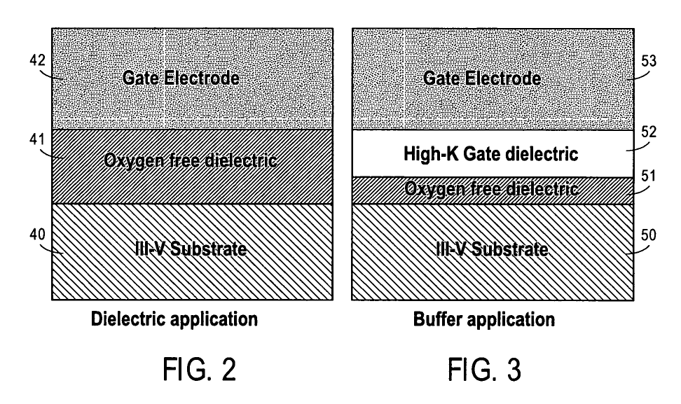

As described below, non-oxygen-containing dielectrics are used to overcome the problem illustrated in FIG. 1. In one embodiment, a dielectric is formed with nitrogen and no oxygen is used between the nitrogen-containing dielectric and the Group III-V substrate. No native oxide is permitted to be formed, or alternatively, it is removed if formed. Examples of dielectrics that may be formed are BN, AlN, GaN and Si₃N₄. This is illustrated in FIG. 2 with a Group III-V substrate 40 having an oxygen-free dielectric 41 disposed between the substrate and a gate electrode 42.

FIG. 3 illustrates the oxygen-free dielectric 51 on the Group III-V substrate 50, as a buffer between the substrate and an oxygen-containing dielectric 52. For instance, a high k dielectric 52 may comprise hafnium oxide (HfO₂) and the oxygen-free dielectric 51, one of the nitrogen-containing dielectrics described above. A metal gate 53 with a targeted work function may be used.

A number of different processes can be used to prevent the formation of an oxide layer, such as a native oxide, on the Group III-V substrate. One process is to form the oxygen-free dielectric in the same tool in which the substrate is formed. In this case, it is relatively easy to prevent the wafer from being exposed to oxygen. Another technique is to move the substrate 40 from one tool to another in a vacuum pod so that the substrate is not exposed to oxygen before the nitrogen-containing dielectric is formed.

In another embodiment, a layer that scavenges oxygen can be immediately placed on the Group III-V substrate before it is exposed to the atmosphere. A rare earth metal or early transition metal is suitable for this purpose. A carbide layer with a band gap of 3 or greater would also serve this purpose. The layer is etched back to remove the oxygen before the oxygen-free dielectric is formed.

A transistor is completed from the structure of FIGS. 2 and 3 by adding a source and drain region.

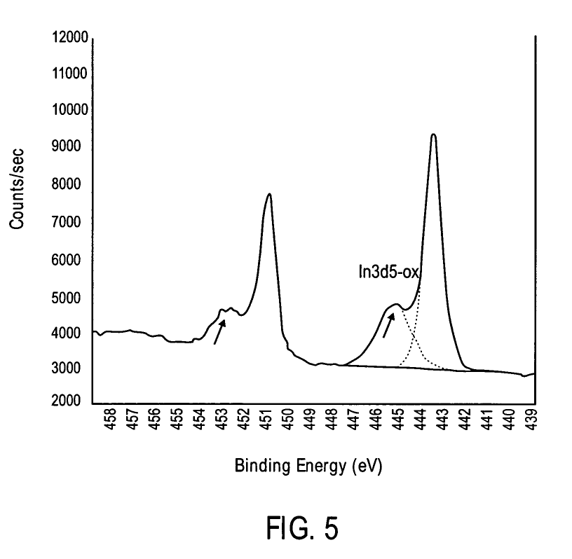

The lack of oxygen at the interface between a Group III-V material using the above process is illustrated in FIGS. 4 and 5 by the X-ray photo-electron spectroscopy diagrams. In FIG. 4, a diagram for antimony (Sb) shows the absence of stable oxidation of Sb for this Group V material. In the diagram the ordinate represents intensity in terms of counts per second as plotted against the binding energy. The diagram illustrates the oxide intensity versus the binding for a particular bond. As can be seen for the two stable forms of an oxide of antimony (Sb₂O₃ and Sb₂O₅), all but one of the counts are below the zero state (Sb-elemental) for Sb.

Similarly in FIG. 5, the XPS graph for indium shows that the only oxygen-bearing compound is well below the two peaks representing the metallic or zero state.

An oxygen-free dielectric makes possible the fabrication of a high performance enhancement made transistor since it eliminates the problems discussed in conjunction with FIG. 1.

Thus, an improved transistor has been described with an oxygen-free interface with a Group III-V substrate.

What is claimed is:

1. A method for fabricating a Group III-V device comprising:
growing a Group III-V region;
forming a first insulating layer on the region without forming an oxygen containing material in the Group III-V region at an interface between the first insulating layer and the Group III-V region; and
forming a gate on the first insulating layer.

2. The method defined by claim 1, wherein the first insulating layer is formed with nitrogen.

3. The method defined by claim 2, wherein the first insulating layer comprises silicon nitride.

4. The method defined by claim 1, wherein the forming of a first insulating layer comprises using a rare earth metal to scavenge oxygen from the surface of the Group III-V region.

5. The method defined by claim 1, including forming a second insulating layer over the first insulating layer before forming the gate, the second insulating layer being of a different material than the first insulating layer.

6. The method defined by claim 5, wherein the second insulating layer contains oxygen.

7. The method defined by claim 5, wherein the first insulating layer has a high dielectric constant.

8. The method defined by claim 5, wherein the gate comprises a metal.

9. The method defined by claim 1, wherein the Group III-V region comprises InSb.

10. The method defined by claim 9, including forming of a source and drain region.

11. The method defined by claim 10, wherein the insulating layer comprises nitrogen.

12. A method for fabricating a Group III-V device comprising:
growing a Group III-V region;
forming a first insulating layer which includes nitrogen on a surface of the Group III-V region without the presence of oxygen in the interface between the surface of the Group III-V region and the first insulating layer; and
forming a gate on the insulating layer.

13. The method defined by claim 12, wherein the first insulating layer and Group III-V region are formed in the same tool.

14. The method defined by claim 12, wherein the first insulating layer is formed in a different tool than used for growing the Group III-V region, and including moving from one tool to the other using a vacuum pod.

15. The method defined by claim 12, including forming a second oxygen-containing dielectric layer between the first insulating layer and the gate.

16. The method defined by claim 15, wherein the second insulating layer comprises a high-k dielectric and the gate comprises a metal.

17. A transistor comprising:
a substrate comprising Group III-V compound;
a non-oxygen containing dielectric disposed directly on the Group III-V substrate; and
a gate disposed on the dielectric.

18. The transistor of claim 17, wherein the dielectric comprises a nitrogen-containing compound.

19. The transistor of claim 18, wherein an oxygen-containing dielectric is disposed between the non-oxygen containing dielectric and the gate.

20. The transistor of claim 19, wherein the oxygen-containing dielectric is a high-k dielectric.

21. The transistor of claim 20, wherein the gate is metal.
